(19) United States
(12) Patent Application Publication
(10) Pub. No.: US 2011/0108714 A1
(43) Pub. Date: May 12, 2011

(54) SMALL TYPE PHOTO-INTERRUPTER AND FABRICATION METHOD THEREOF

(76) Inventors: Chia-Feng Yang, Taipei Hsien (TW); Chih-Wei Liao, Taipei Hsien (TW); Chun-Chih Liang, Taipei Hsien (TW)

(21) Appl. No.: 12/907,980

(22) Filed: Oct. 19, 2010

(30) Foreign Application Priority Data
Nov. 12, 2009 (TW) 098138447

(51) Int. Cl. H01J 40/14; H01L 31/18

(52) U.S. Cl. 250/216; 438/24; 257/E33.076

(57) ABSTRACT

A small type photo-interrupter and a fabrication method of small type photo-interrupter. The fabrication method of small type photo-interrupter includes removing a portion of the surface of the substrate between the light-emitter and the light-sensor and forming an opaque sealing member on the place where the portion of the substrate is removed.

### BACKGROUND OF THE INVENTION

1. Field of the Invention

The present invention relates to a method of fabricating a small type photo-interrupter, and more particularly, it relates to a method of fabricating a small type photo-interrupter having a high signal/noise ratio.

2. Description of the Related Art

An ordinary small type photo-interrupter includes a light-emitter and a light-sensor. The ordinary small type photo-interrupter determines whether the light-sensor detects light signals or not in order to output sensing signals and therefore the small type photo-interrupter can act as a switching device.

The fabrication method of a conventional small type photo-interrupter includes disposing a light-emitter and a light-sensor on a surface of a substrate simultaneously. A first molding process is then performed to inject a transparent sealant on a surface of the light-emitter and a surface of the light-sensor so that two transparent sealing members are formed respectively. Next a second molding process is performed to form an opaque sealant on the peripheral region of the transparent sealing members so that the pathway of light between the light-emitter and the light-sensor is blocked by the opaque sealant. Lastly, to complete the fabrication of the small type photo-interrupter unit, a unit cutting process is performed on the small type photo-interrupter to trim off any excess opaque sealant and excess substrate.

According to the above-mentioned fabrication method, since the substrate thickness of the substrate for positioning the light-emitter is too slim, the transparent sealant is very likely to overflow towards the region between the light-emitter and the light-sensor during the first molding process, and therefore light emitted by the light-emitter would enter the light-sensor side through the overflowed transparent sealant. On the other hand, the substrate may not be able to block the light effectively, thus a fraction of the light emitted by the light-emitter may reach the light-sensor side through the portion of the substrate below the light-emitter, the portion of the substrate between the light-emitter and the light-sensor and the portion of the substrate below the light-sensor, or through other pathways, resulting in sensing errors of the light-sensor. Accordingly, even without the presence of any reflecting objects, the small type photo-interrupter would still output excessive sensing current (leakage current), affecting the signal/noise ratio of the output signals of the small type photo-interrupter significantly. In addition, the conventional method of fabricating the small type photo-interrupter further requires a cutting process to trim off the excess opaque sealant from the second molding process that could easily affect the dimension tolerance of the small type photo-interrupter, causing thickness misfit (too thick or too slim) of the opaque sealant as well as affecting the yield of the production.

Thus, developing for new ways which can provide simple and efficient manufacturing processes for the small type photo-interrupters while avoiding a high leakage current has become one of the primary objectives for the industry.

### SUMMARY OF THE INVENTION

It is one of the primary objectives of the present invention to provide a method of fabricating a small type photo-interrupter which effectively prevents formation of light pathways introduced by sealant overflow or poor light shielding property of the substrate, so as to solve the excessive current leakage problem in the above mentioned conventional small type photo-interrupter.

According to the claimed invention, the present invention provides a method of fabricating a small type photo-interrupter. First a substrate is provided. The substrate includes at least an interrupter unit area defined on a surface of the substrate. The interrupter unit area includes a light-emitter region and a light-sensor region. Then a portion of the substrate between the light-emitter region and the light-sensor region is removed, and a light-emitter and a light-sensor are disposed on the light-emitter region and the light-sensor region of the substrate respectively. Transparent sealing members are formed on the light-emitter region and the light-sensor region respectively. The transparent sealing members cover the light-emitter and the light-sensor respectively. Lastly, an opaque sealing member is formed in the interrupter unit area and disposed outside the light-sensor region and the light-emitter region.

According to the claimed invention, the present invention further provides a small type photo-interrupter, including: a substrate including a light-emitter region and a light-sensor region defined on a surface of the substrate, the substrate having a non-continuous shape between the light-emitter region and the light-sensor region; a light-emitter disposed on the surface of the substrate in the light-emitter region; a light-sensor disposed on the surface of the substrate in the light-sensor region; two transparent sealing members disposed in the light-emitter region and the light-sensor region respectively, covering the light-emitter and the light-sensor respectively; and an opaque sealing member disposed on the substrate outside the light-sensor region and the light-emitter region and disposed on the substrate between the light-sensor region and the light-emitter region.

Since the method of fabricating the small type photo-interrupter in accordance to the present invention includes removing a portion of the substrate between the light-emitter and the light-sensor to form the blocking recess as well as forming the opaque sealing member between the light-emitter and the light-sensor and in the blocking recess, the opaque sealing member can effectively block the light entering from the substrate between the light-emitter and the light-sensor so as to solve the light leakage problem caused by transparent sealant overflow in the conventional molding processes, suppressing the current leakage issues caused by the light leakage and raising the signal/noise ratio of the small type photo-interrupter effectively.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 5 are schematic process diagrams illustrating a method of fabricating a small type photo-interrupter in accordance to a first embodiment of the present invention.

FIG. 6 to FIG. 8 are schematic process diagrams illustrating a method of fabricating a small type photo-interrupter in accordance to a second embodiment of the present invention.

FIG. 9 to FIG. 13 are schematic process diagrams illustrating a method of fabricating a small type photo-interrupter in accordance to a third embodiment of the present invention.

### DETAILED DESCRIPTION OF THE INVENTION

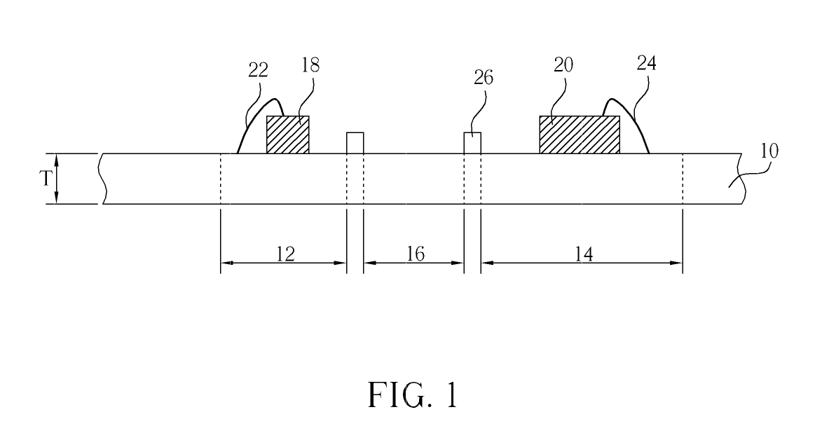

Referring to FIG. 1 to FIG. 5, FIG. 1 to FIG. 5 are schematic process diagrams illustrating a method of fabricating a small type photo-interrupter in accordance to a first embodiment of the present invention. First, as illustrated in FIG. 1, a substrate 10 is provided, and the substrate 10 is preferably a printed circuit board (PCB). The substrate 10 has an original thickness T and includes a light-emitter region 12, a light-sensor region 14 and a photo interrupting region 16 defined on the surface of the substrate 10. The photo interrupting region 16 is disposed between the light-emitter region 12 and the light-sensor region 14. Then a light-emitter 18 and a light-sensor 20 are disposed on the surface of the substrate 10 in the light-emitter region 12 and on the surface of the substrate 10 in the light-sensor region 14, respectively. The light-emitter 18 in accordance to this embodiment of the present invention may be a light-emitting diode chip/die, e.g. an infrared light-emitting diode chip/die, and the light-sensor 20 may be a phototransistor chip/die. Therefore, the process for disposing and fixing the light-emitter 18 and the light-sensor 20 on the substrate 10 may include a chip/die attachment/bonding process, and the light-emitter region 12 and the light-sensor region 14 are attachment regions of the light-emitter 18 and the light sensor 20 on the substrate 10, respectively. A wire bonding process is then performed to electrically connect the light-emitter 18 and the light-sensor 20 to the substrate 10 through a conductive wire 22 and another conductive wire 24, respectively. Subsequently, a sealant blocking part 26 may be optionally formed between the light-emitter region 12 and the light-sensor region 14 or formed on two sides of the photo interrupting region 16, where the sealant blocking part 26 can be made of copper foil material.

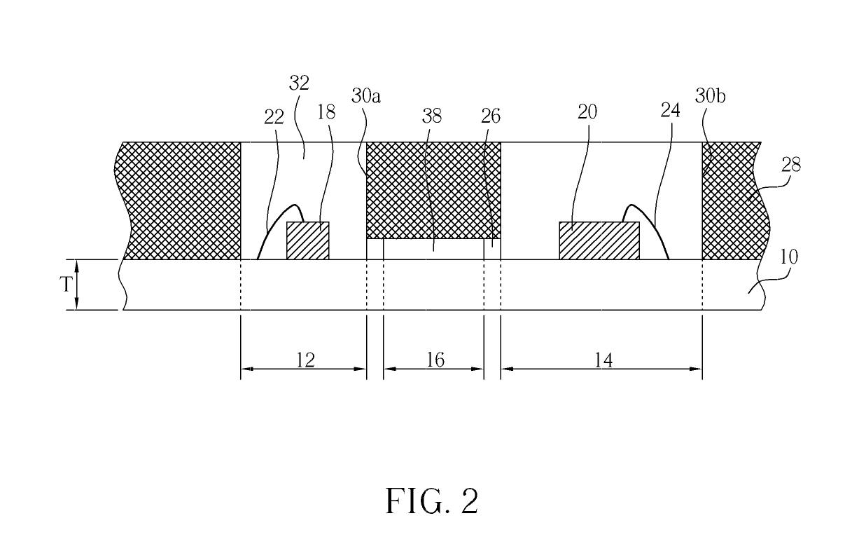

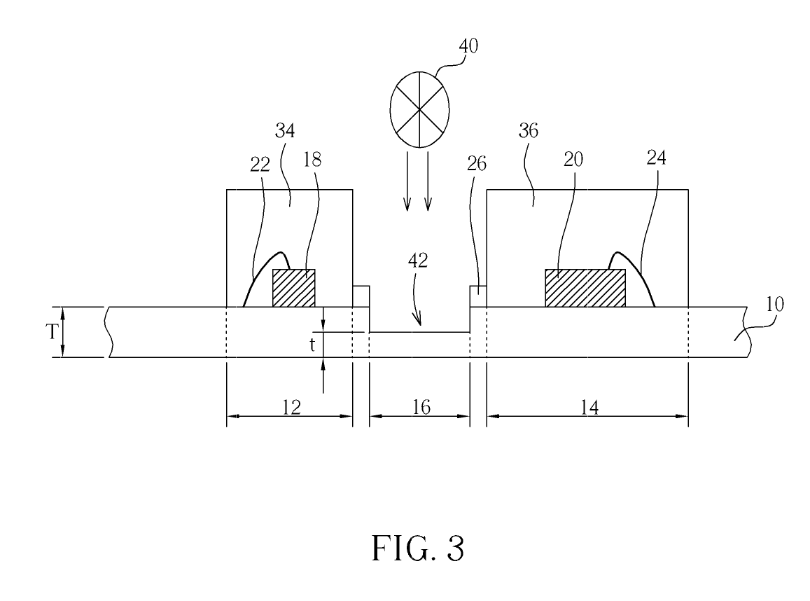

Referring to FIG. 2, transparent sealing members are formed in the light-emitter region and the light-sensor region respectively, covering the light-emitter and the light-sensor respectively, for instance, by the following steps. A molding process is performed by using a mold 28 which includes two molding cavities 30a and 30b. The mold 28 is disposed on the surface of the substrate 10 and the molding cavity 30a and the molding cavity 30b are corresponding to the light-emitter region 12 and the light-sensor region 14, respectively. Then a transparent sealant 32 is injected into the molding cavity 30a and the molding cavity 30b. Once the transparent sealant 32 injected into the molding cavity 30a and the molding cavity 30b is cooled and solidified, a transparent sealing member 34 and another transparent sealing member 36 are formed in the light-emitter region 12 and the light-sensor region 14, respectively. The transparent sealing member 34 and the transparent sealing member 36 cover the light-emitter 18 and the light-sensor 20, respectively, as illustrated in FIG. 3. It is to be noted that, during the molding process, the mold 28 corresponding the portion of the substrate 10 between the light-emitter region 12 and the light-sensor region 14 may include a cavity 38 for containing the sealant blocking part 26 protruded on the surface of the substrate 10. However, if the sealant blocking part 26 is not formed on the substrate 10 after the die attachment process and the wire bonding process, the mold 28 may exclude the cavity 38.

Subsequently, referring to FIG. 3, after the molding process, the mold 28 is removed and a cutting process is performed by using a blade 40 to cut and remove a portion of the surface of the substrate 10 in the photo interrupting region 16, forming a blocking recess 42 on the surface of the substrate 10 between the light-emitter region 12 and the light-sensor region 14. In a preferred embodiment, the substrate 10 below the blocking recess 42 has a thickness t, and the thickness t is preferably ranging between about ¼ and about ½ of the original thickness T of the substrate 10 provided that the strength of the substrate 10 is maintained so that the thickness of the remaining substrate 10 below the blocking recess 42 will not be too thin to maintain the functionality and reliability of the substrate 10.

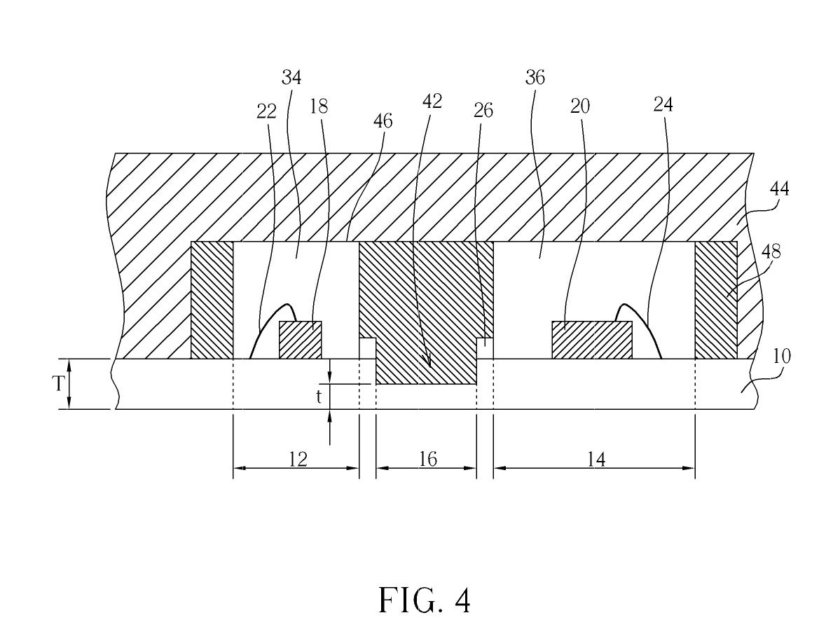

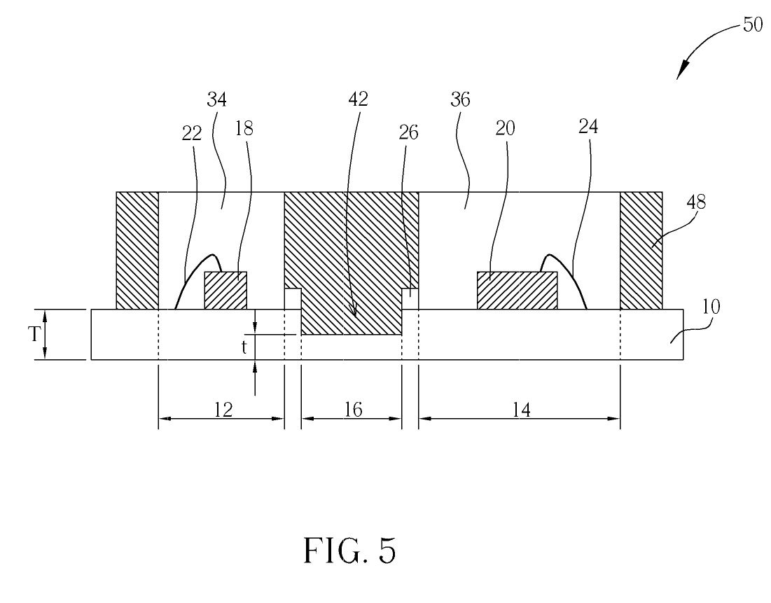

Then, as illustrated in FIG. 4, a mold 44 is used to cover the surface of the substrate 10, and an injection molding process is performed to form an opaque sealing member 48 on the surface of the substrate 10. The opaque sealing member 48 is disposed in the photo interrupting region 16 and in a portion of the substrate 10 outside the light-emitter region 12 and the light-sensor region 14. In other words, the opaque sealing member 48 surrounds the transparent sealing member 34 and the transparent sealing member 36 while filling the blocking recess 42 at the same time. The mold 44 includes a molding cavity 46, and the molding cavity 46 defines the structural shape of the opaque sealing member 48. During the injection molding process, an opaque liquid plastic material (e.g. black plastic material) is injected into the molding cavity 46. Once the plastic material solidifies, it directly forms the opaque sealing member 48 with the final dimension and appearance of the small type photo-interrupter. The opaque sealing member 48 may be used as the reflector of the small type photo-interrupter. Referring to FIG. 5, after the mold 44 is removed, a unit cutting process may be optionally performed, e.g. cutting the substrate 10 by the unit size of the small type photo-interrupter, to form an independent small type photo-interrupter 50.

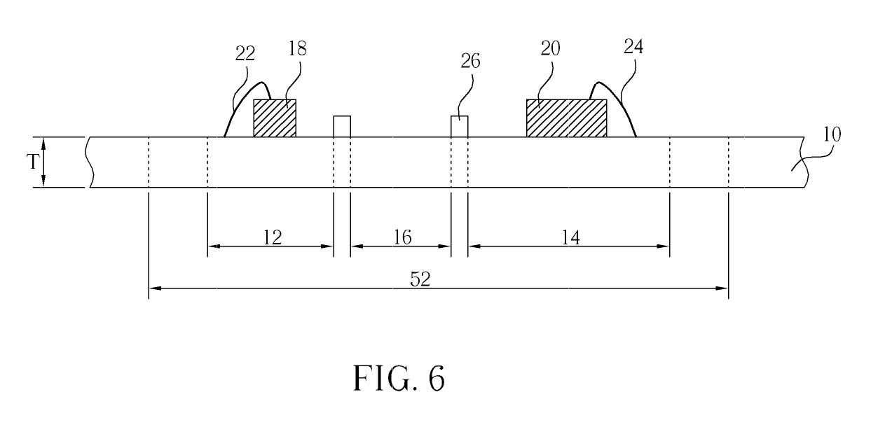

FIG. 6 to FIG. 8 are schematic process diagrams illustrating a method of fabricating a small type photo-interrupter in accordance to a second embodiment of the present invention. To simplify the description and for the convenience of comparison between each of the embodiments of the present invention, identical elements are denoted by identical numerals. First a substrate 10 is provided, which is preferably a PCB substrate. The substrate 10 includes at least an interrupter unit area 52 defined on the surface of the substrate 10. The interrupter unit area 52 includes a light-emitter region 12, a light-sensor region 14 and a photo interrupting region 16. Next a die attachment process and a wire bonding process are performed to dispose a light-emitter 18 and a light-sensor 20 in the light-emitter region 12 and the light-sensor region 14, respectively, and to electrically connect the light-emitter 18 and the light-sensor 20 to the substrate 10 through a conductive wire 22 and another conductive wire 24, respectively. Then, at least a sealant blocking part 26 is optionally disposed between the light-emitter region 12 and the photo interrupting region 16 and between the light-sensor region 14 and the photo interrupting region 16.

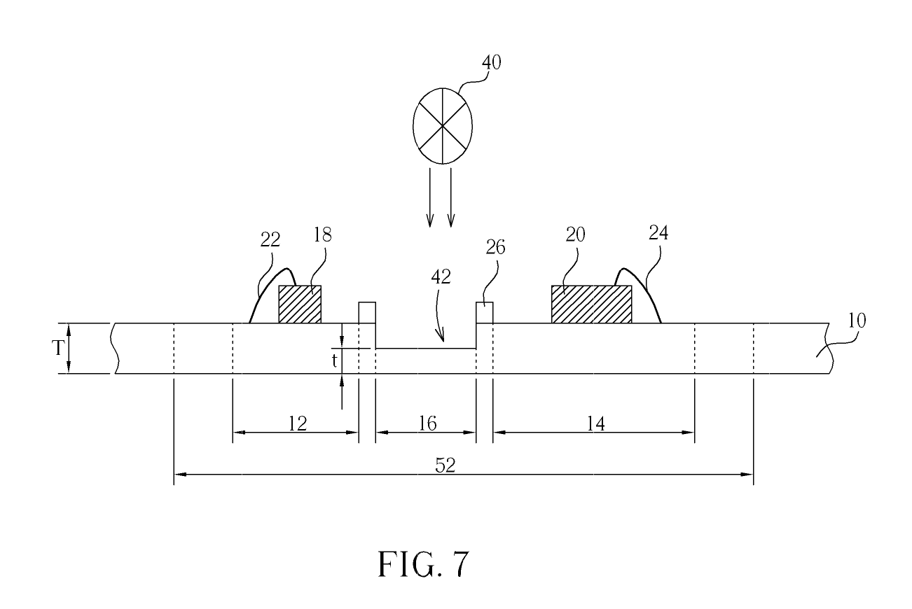

As illustrated in FIG. 7, a cutting process is subsequently performed to cut the surface of the substrate 10 by using a blade 40. The cutting process removes a portion of the surface of the substrate 10 in the photo interrupting region 16 to form a blocking recess 42 so that a thickness t of the substrate 10 below the blocking recess 42 is only ranging between about ¼ and about ½ of the original thickness T of the substrate 10. The thickness t of the substrate 10 is preferably about ½ of the original thickness T of the substrate 10. It is to be noted that, when the surface of the substrate 10 illustrated in FIG. 6 includes a plurality of interrupter unit areas 52, the cutting process can cut off a portion of the substrate 10 of the adjacent interrupter unit areas 52 by using the blade 40 to form the blocking recess 42 in each of the interrupter unit areas 52 simultaneously. In addition, in other embodiments, the cutting process may optionally cut through the substrate 10 so that the blocking recess 42 becomes a through opening of the substrate 10.

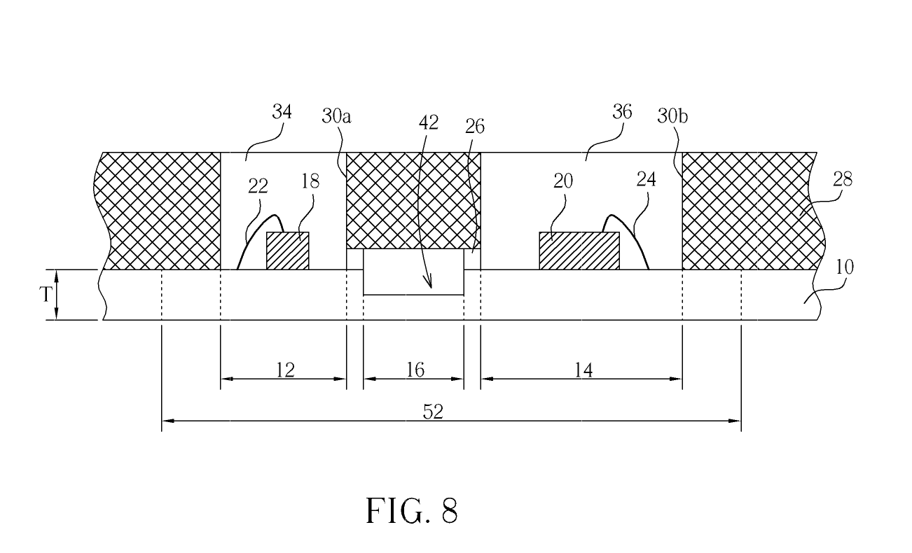

Referring to FIG. 8, a molding process of the chips is then performed by using a mold 28. The mold 28 includes a molding cavity 30a and another molding cavity 30b. The molding cavity 30a and the molding cavity 30b expose the light-emitter region 12 and the light-sensor region 14, respectively. The molding process injects a transparent sealant into the molding cavity 30a and the molding cavity 30b. Once the transparent sealant solidifies, the transparent sealing member 34 and another transparent sealing member 36 are formed. Subsequently, as described in FIG. 4 of the previous embodiment, the mold 28 is removed and an injection molding process is then performed to form an opaque sealing member 48, with an opaque plastic material, on the substrate 10 surrounding the transparent sealing member 34 and the transparent sealing member 36. The opaque sealant member 48 is disposed on the surface of the substrate 10 outside the transparent sealing members 34 and 36. Once the mold of the injection molding is removed, a unit cutting process may be optionally performed to form the small type photo-interrupter 50 of FIG. 5. In other embodiments, the opaque sealing member 48 may be formed by another molding process.

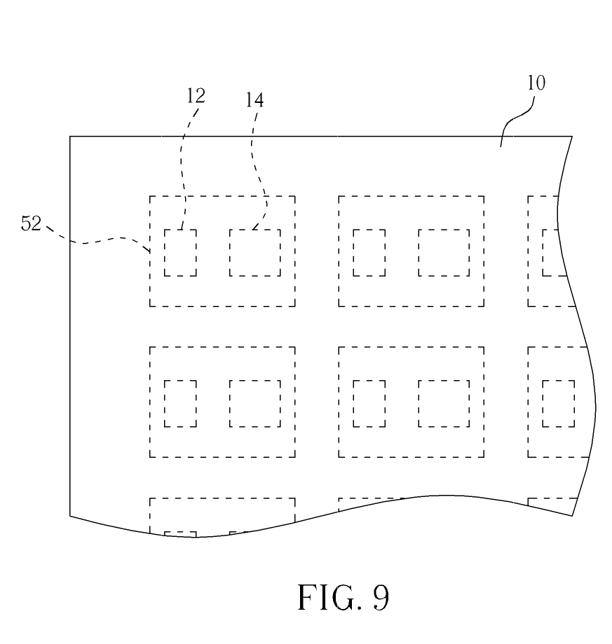

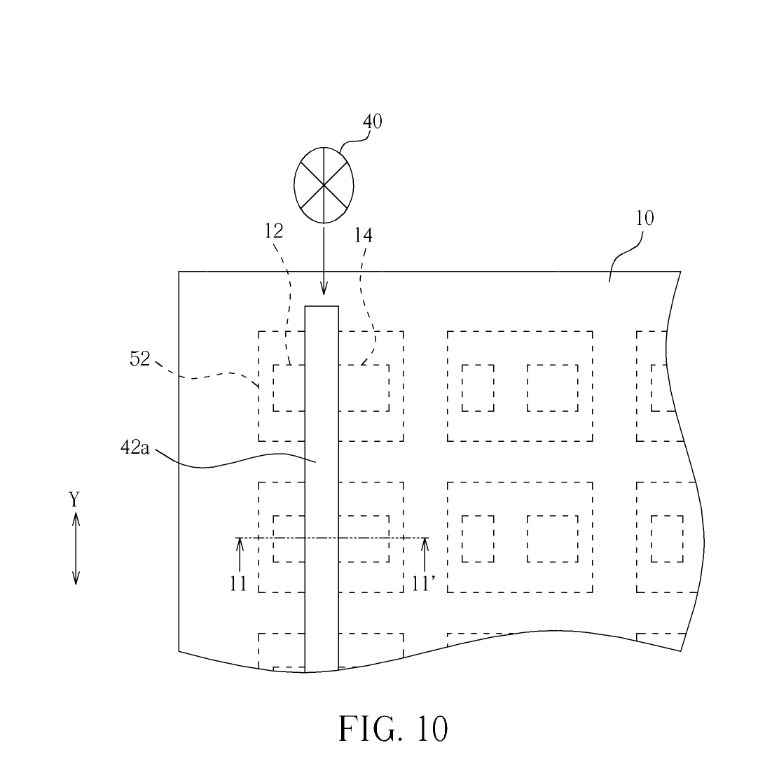

FIG. 9 to FIG. 13 are schematic process diagrams illustrating a method of fabricating a small type photo-interrupter in accordance to a third embodiment of the present invention. Identical elements appeared in FIG. 1 to FIG. 8 are denoted by identical numerals in the present embodiment. Referring to FIG. 9, first a substrate 10 is provided, e.g. a PCB substrate. The substrate 10 includes a plurality of interrupter unit areas 52 defined on its surface. The interrupter unit areas 52 are aligned in parallel and adjacent to one another and form an array. Each of the interrupter unit areas 52 includes a light-emitter region 12 and a light-sensor region 14. As illustrated in FIG. 10, a cutting process is then performed to remove a portion of the substrate 10 by using a blade 40. For example, in a single cutting step, the adjacent interrupter unit areas 52 disposed aligned in parallel along the direction Y are cut directly so as to remove the portion of the substrate 10 located between the light-emitter region 12 and the light-sensing region 14 of the adjacent interrupter unit areas 52 simultaneously. Alternatively, the cutting process may include a plurality of cutting steps to cut each of the interrupter unit areas 52 along the direction Y in sequence.

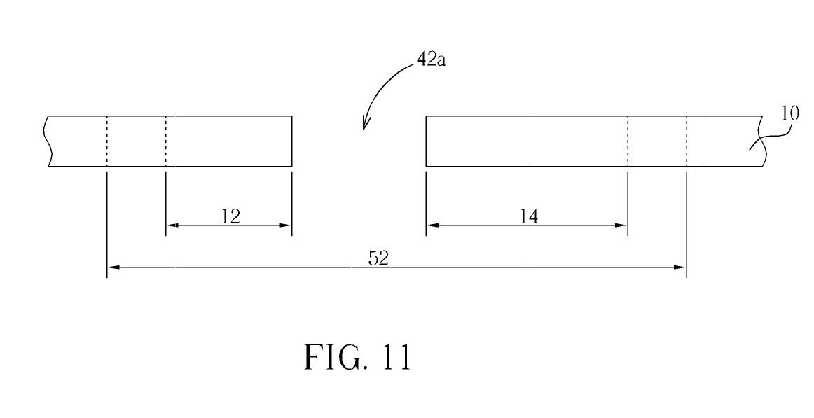

The schematic cross-sectional diagram along line 11-11′ of FIG. 10 is illustrated in FIG. 11. According to FIG. 11, the cutting process cuts through the substrate 10 directly and the substrate 10 between the light-emitter region 12 and the light-sensor region 14 is removed completely. The portion of the substrate 10 removed during the cutting process is also defined as a blocking recess 42a, and the blocking recess 42a is a through opening penetrating through the substrate 10. Thus, the substrate 10 has a non-continuous cross-sectional shape between the light-emitter region 12 and the light-sensor region 14, and the substrate 10 does not exist between the light-emitter region 12 and the light-sensor region 14. However, it is to be noted that the peripheral region of the substrate 10 is not removed and the substrate 10 maintains its original integrity shape including the pluralities of interrupter unit areas 52 after the cutting process. In other embodiments, the cutting process may not cut through the substrate 10 thoroughly while cutting the substrate 10 but only remove the substrate 10 with the thickness between about ½ and about ¾ of the original thickness to form a blocking recess (not illustrated in the figure) between the light-emitter region 12 and the light-sensor region 14, having a thickness between about ¼ to about ½ of the original thickness of the substrate 10.

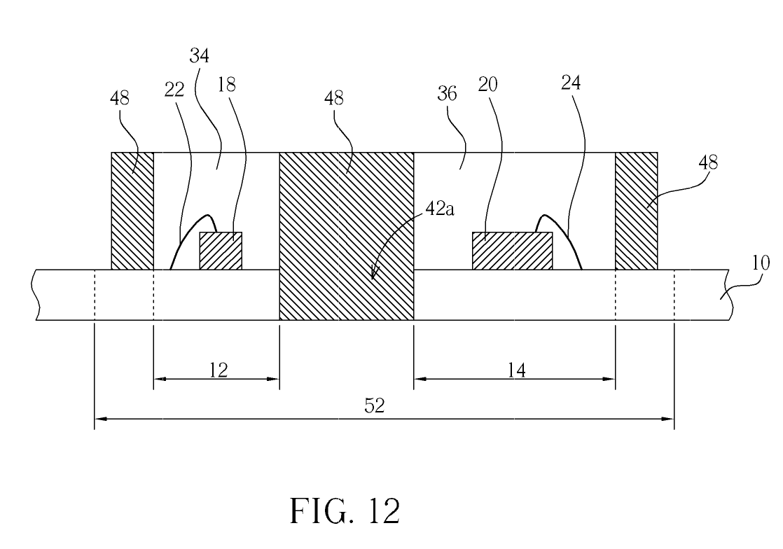

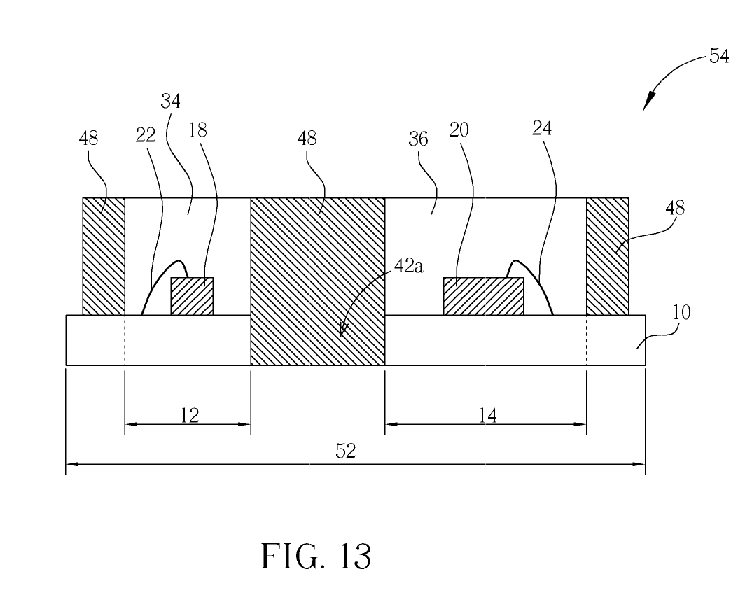

Referring to FIG. 12, FIG. 12 is the process continuation of FIG. 11. A die attachment process and a wire bonding process are then performed to attach a light-emitter 18, a light-sensor 20, a conductive wire 22 and another conductive wire 24 to the light-emitter region 12 and the light-sensor region 14 of each interrupter unit area 52. The conductive wire 22 is electrically connected to the light-emitter 18 and the substrate 10, respectively. The conductive wire 24 is electrically connected between the light-sensor 20 and the substrate 10, respectively. Next a molding process by using a mold is performed to form a transparent sealing member 34 and another transparent sealing member 36 of each interrupter unit area 52. Finally, an injection molding process or another molding process is performed to form opaque sealing members 48. In this embodiment, the blocking recess 42a is a through opening of the substrate 10, and the opaque sealing member 48 is filled into the blocking recess 42a. A unit cutting process is subsequently performed to cut the substrate 10 along the boundaries of the interrupter unit areas 52, forming independent units of the small type photo-interrupters 54, as illustrated in FIG. 13.

In other embodiments of the present invention, the die attachment process and wire bonding process may first be performed on the substrate 10 of FIG. 9 to dispose a light-emitter 18 and a light-sensor 20 in each of the light-emitter regions 12 and each of the light-sensor regions 14, respectively, before the cutting process as illustrated in FIG. 10. Then the fabrication may follow the process sequence similar to that of the second embodiment to form the transparent sealing members 34, 36 and the opaque sealing members 48 in sequence. Subsequently, a unit cutting process is performed to complete the fabrication of each of the small type photo-interrupters 54.

In comparison with the conventional techniques, the present invention first utilizes a cutting process to remove a portion of the surface of the PCB substrate located between the light-emitter region and the light-sensor region. Then the opaque sealing member is formed on regions with the substrate removed to effectively block the light entering to the light-sensor side from the surface of the substrate between the light-emitter and the light-sensor as well as prevent the formation of the light pathways introduced by transparent sealant overflow during conventional molding process. As a result, the current leakage is effectively reduced and the signal/noise ratio of the output signals of the small type photo-interrupter is significantly raised. Furthermore, in the preferred embodiments of the present invention, the opaque sealing member is formed by an injection molding process which directly fabricates the final appearance, dimension and structure of the small type photo-interrupter. Unlike the conventional technique which requires an addition cutting process to remove the opaque sealing member, the present invention avoids the dimensional tolerance introduced from the cutting process.

Those skilled in the art will readily observe that numerous modifications and alterations of the device and method may be made while retaining the teachings of the invention.

What is claimed is:

1. A method of fabricating a small type photo-interrupter, comprising:
providing a substrate comprising at least an interrupter unit area defined on a surface of the substrate, the interrupter unit area comprising a light-emitter region and a light-sensor region;
removing a portion of the substrate located between the light-emitter region and the light-sensor region;
disposing a light-emitter and a light-sensor on the light-emitter region and the light-sensor region of the substrate respectively;
forming a transparent sealing member in the light-emitter region and the light-sensor region respectively, covering the light-emitter and the light-sensor respectively; and
forming an opaque sealing member on the interrupter unit area outside the light-sensor region and the light-emitter region.

2. The method of fabricating the small type photo-interrupter of claim 1, wherein the step of disposing the light-emitter and the light-sensor is performed subsequent to the step of removing the portion of the substrate, and the step of forming the transparent sealing member is performed subsequent to the step of disposing the light-emitter and the light-sensor.

3. The method of fabricating the small type photo-interrupter of claim 2, wherein the step of removing the portion of the substrate comprises cutting the substrate by using a blade.

4. The method of fabricating the small type photo-interrupter of claim 3, wherein the step of cutting comprises cutting through the portion of the substrate located between the light-emitter region and the light-sensor region.

5. The method of fabricating the small type photo-interrupter of claim 3, wherein the step of cutting forms a blocking recess on the surface of the substrate between the light-emitter region and the light-sensor region, and a thickness of the substrate below the blocking recess is reduced to between about ¼ and about ½ of an original thickness of the substrate.

6. The method of fabricating the small type photo-interrupter of claim 3, wherein the surface of the substrate comprises a plurality of the interrupter unit areas aligned in parallel and adjacent to one another, and the step of cutting removes the portion of the substrate between the light-emitter region and the light-sensor region of each of the interrupter unit areas simultaneously, wherein the substrate is cut along the interrupter unit areas to form a plurality of small type photo-interrupters subsequent to the step of forming the opaque sealing member.

7. The method of fabricating the small type photo-interrupter of claim 1, wherein the step of forming the transparent sealing member is performed subsequent to the step of disposing the light-emitter and the light-sensor, and the step of removing the portion of the substrate is performed subsequent to the step of forming the transparent sealing member.

8. The method of fabricating the small type photo-interrupter of claim 7, wherein the step of removing the portion of the substrate comprises cutting the substrate by using a blade.

9. The method of fabricating the small type photo-interrupter of claim 8, wherein the step of cutting comprises cutting through the portion of the substrate located between the light-emitter region and the light-sensor region.

10. The method of fabricating the small type photo-interrupter of claim 8, wherein the step of cutting forms a blocking recess on the surface of the substrate between the light-emitter region and the light-sensor region, and a thickness of the substrate below the blocking recess is reduced to between about ¼ and about ½ of an original thickness of the substrate.

11. The method of fabricating the small type photo-interrupter of claim 8, wherein the surface of the substrate comprises a plurality of the interrupter unit areas aligned in parallel and adjacent to one another, and the step of cutting removes the portion of the substrate between the light-emitter region and the light-sensor region of each of the interrupter unit areas simultaneously, wherein the substrate is cut along the interrupter unit areas to form a plurality of small type photo-interrupters subsequent to the step of forming the opaque sealing member.

12. The method of fabricating the small type photo-interrupter of claim 1, wherein the step of removing the portion of the substrate is performed subsequent to the step of disposing the light-emitter and the light-sensor, and the step of forming the transparent sealing member is performed subsequent to the step of the step of removing the portion of the substrate.

13. The method of fabricating the small type photo-interrupter of claim 12, wherein the step of removing the portion of the substrate comprises cutting the substrate by using a blade.

14. The method of fabricating the small type photo-interrupter of claim 13, wherein the step of cutting comprises cutting through the portion of the substrate located between the light-emitter region and the light-sensor region.

15. The method of fabricating the small type photo-interrupter of claim 13, wherein the step of cutting forms a blocking recess on the surface of the substrate between the light-emitter region and the light-sensor region, and a thickness of the substrate below the blocking recess is reduced to between about ¼ and about ½ of an original thickness of the substrate.

16. The method of fabricating the small type photo-interrupter of claim 13, wherein the surface of the substrate comprises a plurality of the interrupter unit areas aligned in parallel and adjacent to one another, and the step of cutting removes the portion of the substrate between the light-emitter region and the light-sensor region of each of the interrupter unit areas simultaneously, wherein the substrate is cut along the interrupter unit areas to form a plurality of small type photo-interrupters subsequent to the step of forming the opaque sealing member.

17. The method of fabricating the small type photo-interrupter of claim 1, further comprising disposing at least a sealant blocking part on the surface of the substrate between the light-emitter region and the light-sensor region prior to the step of forming the transparent sealing member.

18. A small type photo-interrupter, comprising:
a substrate comprising a light-emitter region and a light-sensor region defined on a surface of the substrate, the substrate having a non-continuous shape between the light-emitter region and the light-sensor region;
a light-emitter disposed on the surface of the substrate in the light-emitter region;
a light-sensor disposed on the surface of the substrate in the light-sensor region;
two transparent sealing members disposed in the light-emitter region and the light-sensor region respectively, covering the light-emitter and the light-sensor respectively; and
an opaque sealing member disposed on the substrate outside the light-sensor region and the light-emitter region and between the light-sensor region and the light-emitter region.

19. The small type photo-interrupter of claim 18, wherein the non-continuous shape between the light-emitter region and the light-sensor region comprises a blocking recess or a through opening filled by the opaque sealing member.

20. The small type photo-interrupter of claim 18, further comprising at least a sealant blocking part disposed on the surface of the substrate between the light-emitter region and the light-sensor region.
